(19) United States
(12) Patent Application Publication
(10) Pub. No.: US 2016/0329269 A1
(43) Pub. Date: Nov. 10, 2016

(54) CHIP PACKAGE STRUCTURE AND MANUFACTURING METHOD THEREOF

(71) Applicants: ChipMOS Technologies Inc., Hsinchu (TW); ChipMOS Technologies (Bermuda) Ltd., Hamilton (BM)

(72) Inventor: Chi-Jin Shih, Hsinchu (TW)

(21) Appl. No.: 14/874,486

(22) Filed: Oct. 5, 2015

(30) Foreign Application Priority Data
May 4, 2015 (TW) 104114146

(51) Int. Cl. H01L 23/495; H01L 21/56; H01L 23/31

(52) U.S. Cl. CPC H01L 23/49548; H01L 23/4952; H01L 23/49513; H01L 23/3142; H01L 21/563; H01L 2021/60022

(57) ABSTRACT

A chip package structure including a lead frame, a chip, a plurality of solder bumps, a solder resist layer and an encapsulant is provided. The lead frame has a plurality of inner leads. Each of the inner leads has an upper surface, a lower surface, two side surfaces opposite to each other and a bonding area on the upper surface. The chip is disposed on the lead frame and has an active surface. Each of the solder bumps connects the active surface and the bonding area of each of the inner leads. The solder resist layer is disposed on at least one of the lower surface or the two side surfaces of each of the inner leads. The encapsulant covers the lead frame, the chip, the solder bumps and the solder resist layer. A manufacturing method of the chip package structure is also provided.

### CROSS-REFERENCE TO RELATED APPLICATION

This application claims the priority benefit of Taiwan application serial no. 104114146, filed on May 4, 2015. The entirety of the above-mentioned patent application is hereby incorporated by reference herein and made a part of this specification.

### BACKGROUND OF THE INVENTION

1. Field of the Invention

The invention relates to a package structure and a manufacturing method thereof, and particularly relates to a chip package structure and a manufacturing method thereof.

2. Description of Related Art

With recent progress of electronic technologies, electronic products that are more user-friendly and with better performance are continuously developed. Furthermore, these electronic products are designed to satisfy requirements for lightness, slimness, shortness, and compactness. Considering the chip packaging technology, each chip singulated from a wafer is mounted on a carrier by, for example, wire bonding method or flip chip bonding method, wherein the carrier can be a lead frame or a substrate. Taking the lead frame type flip chip package structure as an example, the chip faces the lead frame with the active surface, and is bonded to the lead frame via a plurality of bumps formed on the active surface or on the leads of the lead frame. Then, when the bumps are solder bumps, the reflow process needs to be performed to electrically and structurally connect each of the bumps to the corresponding inner lead. Finally, the molding process is performed to form the encapsulant for covering the lead frame, the chip, and the bumps, so that the manufacturing process of the lead frame type flip chip package structure is completed.

However, during the reflow process, the solder bump is in a molten state, so that the size of the wetting area between the bump and the inner lead cannot be controlled precisely. In addition, to prevent the melted bump from spilling over to the lower surface of the inner lead, which may lead to reduced or inadequate height of the solder bump formed after reflow, currently the width of the inner lead is designed to be greater than the width of the bump. Such method can prevent the melted bump from spilling over to the lower surface of the inner lead, but the pitch between two adjacent inner leads is enlarged, so that the requirement for fine pitch cannot be achieved, and the pin density of the chip package structure cannot be increased.

### SUMMARY OF THE INVENTION

The invention provides a chip package structure which has a higher pin density or pin count.

The invention provides a manufacturing method of a chip package structure which has a higher pin density or pin count.

The invention provides a chip package structure which includes a lead frame, a chip, a plurality of solder bumps, a solder resist layer and an encapsulant. The lead frame has a plurality of inner leads. Each of the inner leads has an upper surface, a lower surface, two side surfaces opposite to each other and connecting the upper surface and the lower surface, and a bonding area located on the upper surface. The chip is disposed on the lead frame and has an active surface. Each of the solder bumps connects the active surface and the bonding area of each of the inner leads. The solder resist layer is disposed on at least one of the lower surface or the two side surfaces of each of the inner leads, and at least corresponding to the bonding area of each of the inner leads. The encapsulant covers the lead frame, the chip, the solder bumps and the solder resist layer.

The present invention further provides a manufacturing method of a chip package structure which includes the following steps. Firstly, a lead frame is provided. The lead frame has a plurality of inner leads. Each of the inner leads has an upper surface, a lower surface, two side surfaces opposite to each other and connecting the upper surface and the lower surface, and a bonding area on the upper surface. A solder resist layer is formed on at least one of the lower surface or the two side surfaces of each of the inner leads, and at least corresponding to the bonding area of each of the inner leads. A chip is mounted on the lead frame via flip-chip bonding, wherein the chip has an active surface, and the active surface is bonded to the bonding area of each of the inner leads via a plurality of solder bumps. Then, the solder bumps are reflowed. Finally, an encapsulant is formed, wherein the encapsulant covers the lead frame, the chip, and the solder bumps.

Based on the above, the solder resist layer is formed on the inner lead of the lead frame before the chip is mounted on the lead frame via flip chip bonding in the invention, wherein the solder resist layer can be disposed on the lower surface or the two side surfaces of the inner lead. Therefore, when the solder bumps located between the chip and the lead frame are reflowed to be electrically and structurally connected with the inner leads, the melted solder bumps can be prevented from spilling over to the lower surfaces of the inner leads so that the height of the solder bumps formed after reflow can be assured to meet the requirement of standoff between the chip and the lead frame. In contrast with the conventional technology in which the width of the inner lead is designed to be greater than the width of the bump in order to prevent the melted bump from spilling over to the lower surface of the inner lead, the formation of the solder resist layer in the present invention can prevent the melted solder bump from spilling over to the lower surface of the corresponding inner lead without enlarging the width of the inner lead such that the width of the inner lead and the pitch between the two adjacent inner leads can both be reduced to achieve the requirement for fine pitch, and the pin density or pin count of the chip package structure can be increased.

In order to make the aforementioned and other features and advantages of the invention more comprehensible, embodiments accompanying figures are described in details below.

### BRIEF DESCRIPTION OF THE DRAWINGS

FIG. 1A to FIG. 1E depict a manufacturing process of the chip package structure according to an embodiment of the invention.

FIG. 1F is a local schematic view of a cross-section of the chip package structure along line A-A in FIG. 1E.

FIG. 2A is a schematic view of a chip package structure according to another embodiment of the invention.

FIG. 2B is a local schematic view of a cross-section of the chip package structure along line B-B in FIG. 2A.

FIG. 3A is a schematic view of a chip package structure according to another embodiment of the invention.

FIG. 3B is a local schematic view of a cross-section of the chip package structure along line C-C in FIG. 3A.

FIG. 4A is a schematic view of a chip package structure according to another embodiment of the invention.

FIG. 4B is a local schematic view of a cross-section of the chip package structure along line D-D in FIG. 4A.

### DESCRIPTION OF THE EMBODIMENTS

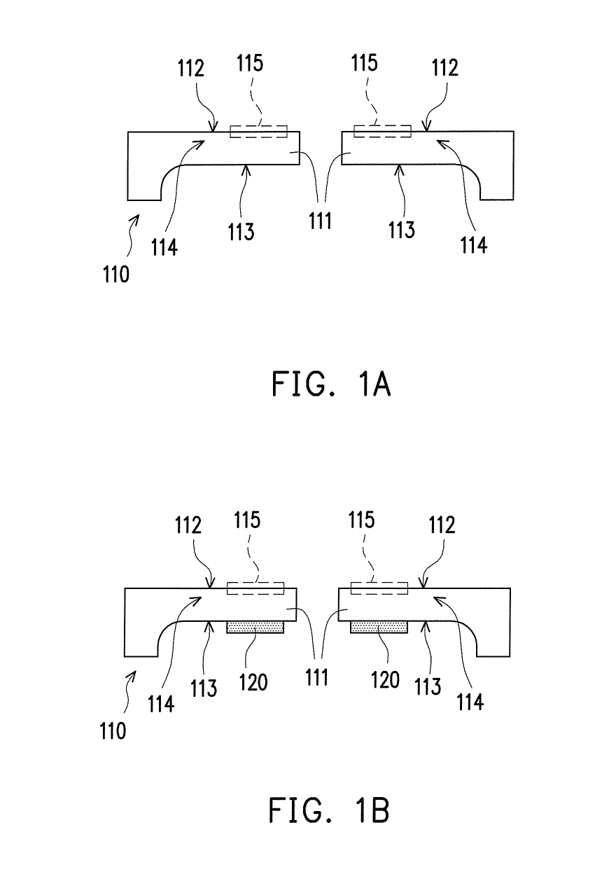

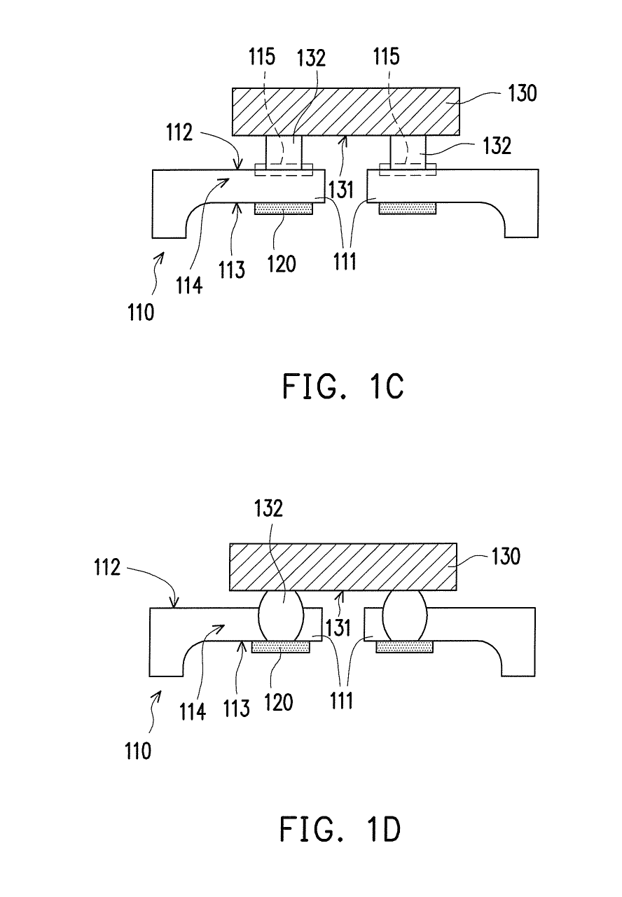

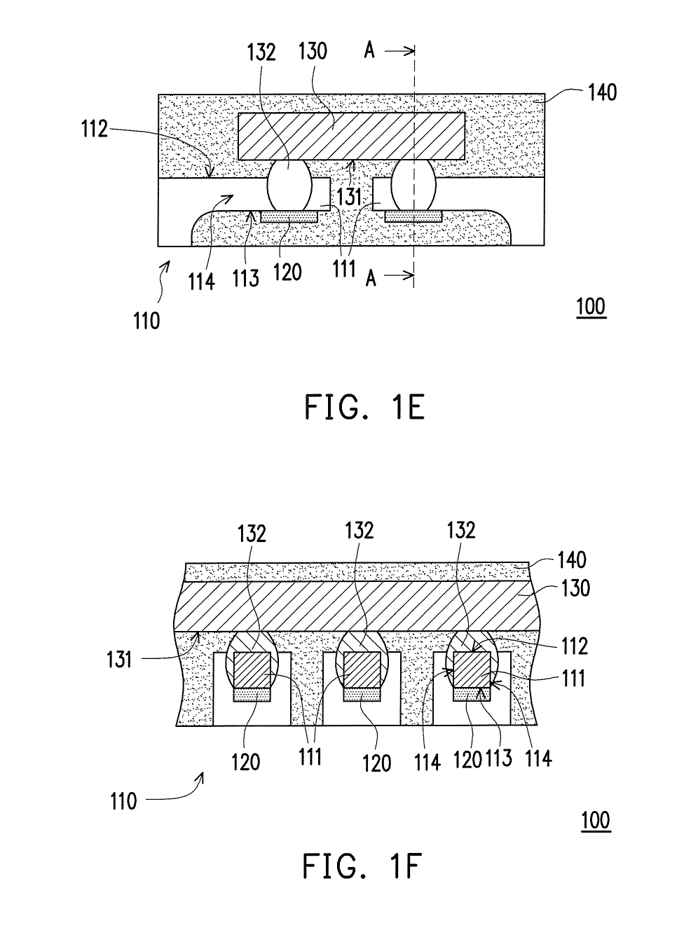

FIG. 1A to FIG. 1E depict a manufacturing process of the chip package structure according to an embodiment of the invention. FIG. 1F is a local schematic view of a cross-section of the chip package structure along line A-A in FIG. 1E. Firs, referring to FIG. 1A, a lead frame 110 is provided to serve as a carrier. The lead frame 110 has a plurality of inner leads 111. Each of the inner leads 111 has an upper surface 112, a lower surface 113 opposite to the upper surface 112, two side surfaces 114 (depicted in FIG. 1F) opposite to each other and connecting the upper surface 112 and the lower surface 113, and a bonding area 115 located on the upper surface 112.

Referring to FIG. 1B, a solder resist layer 120 is formed on the lower surface 113 of each of the inner leads 111, and at least corresponding to the bonding area 115 of each of the inner leads 111. To be more specific, the solder resist layer 120 is, for example, formed on the lower surface 113 of each of the inner leads 111 by printing process, and the solder resist layer 120 covers an area of an orthogonal projection of the bonding area 115 on the lower surface 113 of each of the inner leads 111 so as to be aligned with the bonding area 115 of the corresponding inner lead 111. The material of the solder resist layer 120 can be nickel, titanium, titanium-tungsten alloy, palladium, platinum, silver, solder resist ink, or insulating resin, but the invention is not limited thereto.

Then, referring to FIG. 1C, a chip 130 is mounted on the lead frame 110 via flip chip bonding, wherein the chip 130 has an active surface 131. More specifically, the chip 130 is disposed on the lead frame 110 with the active surface 131 facing the upper surface 112 of each of the inner leads 111 of the lead frame 110, and the chip 130 is bonded to the bonding areas 115 of the inner leads 111 by a plurality of solder bumps 132. As shown in FIG. 1C, the solder resist layer 120 on the lower surface 113 of the inner lead 111 is corresponding to the solder bump 132 bonded to the bonding area 115 of the inner lead 111, wherein the material of the solder bumps 132 can be tin, silver, copper, nickel, bismuth, indium, zinc, antimony, or any alloy thereof.

Next, referring to FIG. 1D, the solder bumps 132 are reflowed so that each of the solder bumps 132 is electrically and structurally connected to the corresponding inner lead 111. Finally, referring to FIG. 1E, an encapsulant 140 is formed, wherein the encapsulant 140 covers the lead frame 110, the chip 130, the solder bumps 132 and the solder resist layer 120. Generally, the encapsulant 140 can be epoxy resin or silicon-based compound, and can be used to prevent the chip 130 and the contacts (i.e., the solder bump 132) between the chip 130 and the lead frame 110 from being affected by ambient temperature, moisture, and dust contamination. Up to here, the manufacturing of the chip package structure 100 is completed. It should be noted that, in the manufacturing process of the chip package structure 100 of the present embodiment, the solder resist layer 120 can be removed optionally before forming the encapsulant 140.

As shown in FIG. 1E and FIG. 1F, each of the solder bumps 132 after reflow covers the upper surface 112 and at least part of the two side surfaces 114 of the corresponding inner lead 111. Since the solder resist layer 120 is formed on the lower surface 113 of each of the inner leads 111, and the solder resist layer 120 has non-wettable property with respect to solder, when the solder bumps 132 are reflowed, each of the melted solder bumps 132 would not spill over to the lower surface 113 of the corresponding inner lead 111, and would stop at the side surfaces 114 of the corresponding inner lead 111 to form a spherical shape due to the obstruction of the solder resist layer 120, and the surface tension and cohesion of the solder material. Therefore, the width of each solder bump 132 can be greater than the width of the corresponding inner lead 111, and since the solder bump 132 covers the upper surface 112 and at least part of the two side surfaces 114 of the corresponding inner lead 111, the bonding strength between the chip 130 and the lead frame 110 can be effectively enhanced.

Considering the conventional technology, the width of the inner lead should be designed greater than the width of the bump in order to prevent the melted bump from spilling over to the lower surface or the side surface of the inner lead. For example, when the width of the bump is 80 micrometer (μm), the width of the inner lead should be around 130 μm, and the pitch between the inner leads should be around 250 μm. In comparison with the conventional technology, the melted solder bump 132 can be prevented from spilling over to the lower surface 113 of the corresponding inner lead 111 via the solder resist layer 120 in the present embodiment. Therefore, in the present embodiment, the width of the inner lead 111 can be effectively reduced, and the pitch between the inner leads 111 can also be reduced, so as to increase the pin density or pin count of the chip package structure 100. For example, for the same 80 μm wide bump, the width of the inner lead 111 of the present embodiment can be reduced to around 60 μm, and the pitch between the inner leads 111 can be reduced to around 200 μm.

Other embodiments are described as follows. It should be noted that in the embodiments below identical or similar elements are labelled with identical reference numbers, and the description of the similar technical content will be omitted. Regarding the details of the omitted parts, reference can be made to the previous embodiment, and they will not be repeated in the embodiments below.

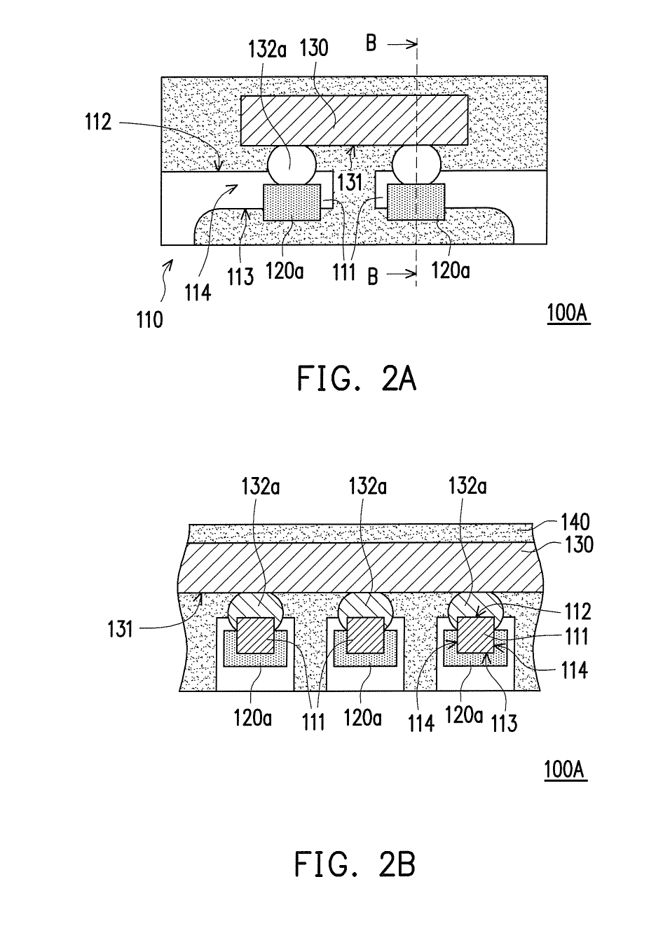

FIG. 2A is a schematic view of a chip package structure according to another embodiment of the invention. FIG. 2B is a local schematic view of a cross-section of the chip package structure along line B-B in FIG. 2A. Referring to FIG. 2A and FIG. 2B, the difference from the chip package structure 100 of the above-mentioned embodiment is that the solder resist layer 120a of the chip package structure 100A of the present embodiment further covers part of an area on the two side surfaces 114 that the bonding area 115 of each of the inner leads 111 extending perpendicularly to the two side surfaces 114. In other words, by disposing the solder resist layer 120a on the two side surfaces 114 of each inner lead 111, each of the melted solder bumps 132a during reflow is blocked by the solder resist layer 120a, and stops at the side surfaces 114 of the corresponding inner lead 111. It should be noted that, in the manufacturing process of the chip package structure 100A of the present embodiment, the solder resist layer 120a is formed on part of the two side surfaces 114 of each of the inner leads 111 at the same time as it is formed on the lower surface 113 of each of the inner leads 111, so that the solder resist layer 120a covers the lower surface 113 of each of the inner leads 111 and part of an area on the two side surfaces 114 that the bonding area 115 of each of the inner leads 111 extending perpendicularly thereto. Similarly, in the manufacturing process of the chip package structure 100A of the present embodiment, the solder resist layer 120a can be removed optionally before forming the encapsulant 140.

On the other hand, since the solder resist layer 120a is also formed on the two side surfaces 114 of the inner lead 111 of the chip package structure 100A in the present embodiment, the flowing distance of the melted solder bump 132a on the side surfaces 114 during reflow is reduced due to the arrangement of the solder resist layer 120a, and the melted solder bump 132a is hence blocked by the solder resist layer 120a and forms a spherical shape due to cohesion. In contrast, the solder resist layer 120 is only disposed on the lower surface 113 of each of the inner leads 111 in the above-mentioned embodiment, such that the melted solder bump 132 during reflow is possible to flow over the entire height of the side surfaces 114 till it is blocked by the solder resist layer 120 to form a spherical shape. In other words, the sinking distance of the melted solder bump 132a during reflow would be smaller than that of the melted solder bump 132, so that a larger space between the chip 130 and the upper surfaces 112 of the inner leads 111 (i.e. standoff) would be maintained. Referring to FIG. 1F and FIG. 2B, the appearance of the solder bump 132a solidified after reflow in the present embodiment is slightly different from the appearance of the solder bump 132 solidified in the above-mentioned embodiment. For example, the width of the solidified solder bump 132a in the present embodiment is larger than the width of the solidified solder bump 132 in the above-mentioned embodiment.

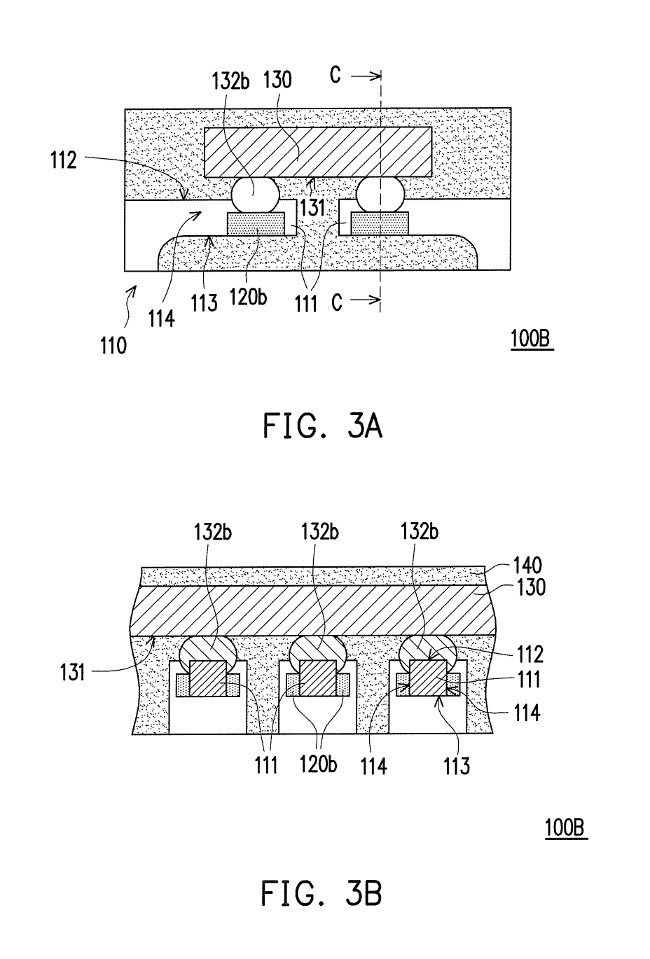

FIG. 3A is a schematic view of a chip package structure according to another embodiment of the invention. FIG. 3B is a local schematic view of a cross-section of the chip package structure along line C-C in FIG. 3A. Referring to FIG. 3A and FIG. 3B, the difference from the chip package structure 100A of the above-mentioned embodiment is that the solder resist layer 120b of the chip package structure 100B of the present embodiment only covers part of an area on the two side surfaces 114 that the bonding area 115 of each of the inner leads 111 extends perpendicularly to the two side surfaces 114, wherein the solder resist layer 120b is, for example, located near the edge relatively closer to the lower surface 113 of each of the inner leads 111. The position of the solder resist layer 120b on the two side surfaces 114 can be adjusted according to the actual requirements; the invention is not limited thereto. In another embodiment, the solder resist layer 120b can extend from the edge close to the lower surface 113 to the other edge close to the upper surface 112. Therefore, the appearance of the solder bump 132b solidified after reflow in the present embodiment can be similar to or different from the appearances of the solidified solder bumps 132 or 132a in the above-mentioned embodiments. It should be noted that, in the manufacturing process of the chip package structure 100B of the present embodiment, the solder resist layer 120b is formed on part of an area on the two side surfaces 114 that the bonding area 115 of each of the inner leads 111 extends perpendicularly thereto, so that the solder resist layer 120b only covers part of the two side surfaces 114 of each of the inner leads 111. Similarly, in the manufacturing process of the chip package structure 100B of the present embodiment, the solder resist layer 120b can be removed optionally before forming the encapsulant 140.

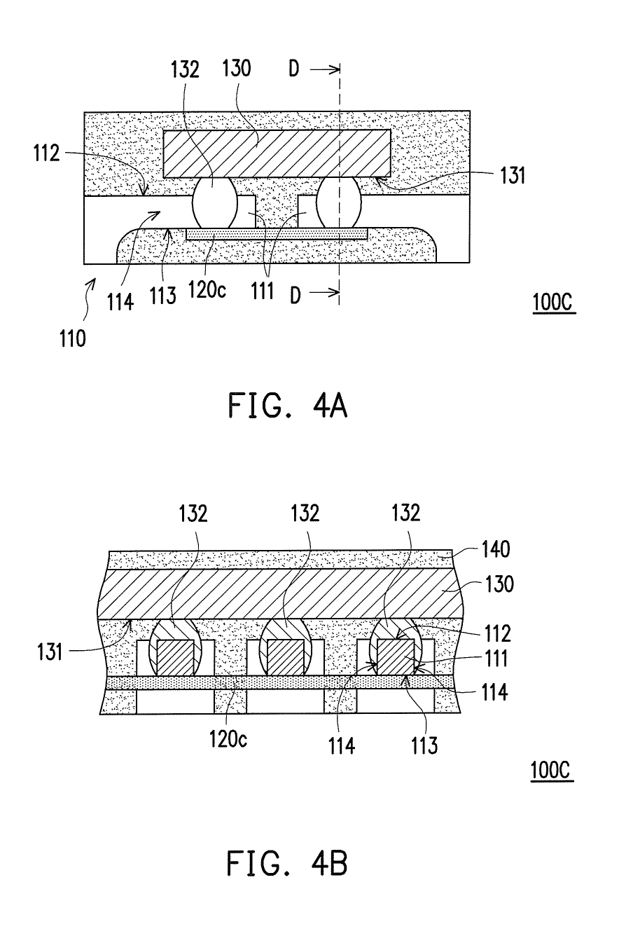

FIG. 4A is a schematic view of a chip package structure according to another embodiment of the invention. FIG. 4B is a local schematic view of a cross-section of the chip package structure along line D-D in FIG. 4A. Referring to FIG. 4A and FIG. 4B, the difference from the chip package structures 100, 100A, or 100B of the above-mentioned embodiments is that the solder resist layer 120c of the chip package structure 100C of the present embodiment is a solder resist tape that is continuously adhered to the lower surfaces 113 of the inner leads 111. Similarly, in the manufacturing process of the chip package structure 100C of the present embodiment, the solder resist layer 120c can be removed optionally before forming the encapsulant 140.

In summary, the solder resist layer is formed on the inner lead of the lead frame before the chip is mounted on the lead frame via flip chip bonding in the invention, wherein the solder resist layer can be disposed on the lower surface or the two side surfaces of the inner lead. Therefore, when the solder bumps located between the chip and the lead frame are reflowed to be electrically and structurally connected with the inner leads, the melted solder bumps can be prevented from spilling over to the lower surfaces of the inner leads so that the height of the solder bumps formed after reflow can be assured to meet the requirement of standoff between the chip and the lead frame. In contrast with the conventional technology in which the width of the inner lead is designed to be greater than the width of the bump in order to prevent the melted bump from spilling over to the lower surface of the inner lead, in the invention, the formation of the solder resist layer can prevent the melted solder bump from spilling over to the lower surface of the corresponding inner lead without enlargint the width of the inner lead such that the width of the inner lead and the pitch between the two adjacent inner leads can both be reduced to achieve the requirement for fine pitch, and the pin density or pin count of the chip package structure can be increased.

Although the invention has been disclosed with reference to the aforesaid embodiments, they are not intended to limit the invention. It will be apparent to one of ordinary skill in the art that modifications and variations to the described embodiments may be made without departing from the spirit and the scope of the invention. Accordingly, the scope of the invention will be defined by the attached claims and not by the above detailed descriptions.

What is claimed is:

1. A chip package structure, comprising:
a lead frame, having a plurality of inner leads, wherein each of the inner leads has an upper surface, a lower surface, two side surfaces opposite to each other and connecting the upper surface and the lower surface, and a bonding area located on the upper surface;
a chip, disposed on the lead frame and has an active surface;
a plurality of solder bumps, wherein each of the solder bumps connects the active surface and the bonding area of each of the inner leads;
a solder resist layer, disposed on at least one of the lower surface or the two side surfaces of each of the inner leads, and at least corresponding to the bonding area of each of the inner leads; and
an encapsulant, covering the lead frame, the chip, the solder bumps, and the solder resist layer.

2. The chip package structure as recited in claim 1, wherein the solder resist layer covers an area of an orthogonal projection of the bonding area on the lower surface of each of the inner leads, and each of the solder bumps covers the upper surface and at least part of the two side surfaces of the inner lead corresponding thereto.

3. The chip package structure as recited in claim 2, wherein the solder resist layer is a solder resist tape that is continuously adhered to the lower surfaces of the inner leads.

4. The chip package structure as recited in claim 2, wherein the solder resist layer further covers part of an area on the two side surfaces that the bonding area of each of the inner leads extends perpendicularly thereto.

5. The chip package structure as recited in claim 1, wherein the solder resist layer covers part of an area on the two side surfaces that the bonding area of each of the inner leads extends perpendicularly thereto, and each of the solder bumps covers the upper surface and part of the two side surfaces of the inner lead corresponding thereto.

6. The chip package structure as recited in claim 1, wherein a width of each of the solder bumps is greater than a width of the inner lead corresponding thereto.

7. The chip package structure as recited in claim 1, wherein the materials of the solder resist layer comprise nickel, titanium, titanium-tungsten alloy, palladium, platinum, silver, solder resist ink, or insulating resin.

8. A manufacturing method of a chip package structure, comprising:
providing a lead frame, wherein the lead frame has a plurality of inner leads, each of the inner leads has an upper surface, a lower surface, two side surfaces opposite to each other and connecting the upper surface and the lower surface, and a bonding area located on the upper surface;
forming a solder resist layer on at least one of the lower surface or the two side surfaces of each of the inner leads, the solder resist layer at least corresponding to the bonding area of each of the inner leads;
mounting a chip on the lead frame via flip-chip bonding, wherein the chip has an active surface, and the active surface is bonded to the bonding area of each of the inner leads via a plurality of solder bumps;
reflowing the solder bumps; and
forming an encapsulant, wherein the encapsulant covers the lead frame, the chip, and the solder bumps.

9. The manufacturing method of the chip package structure as recited in claim 8, wherein the solder resist layer covers an area of an orthogonal projection of the bonding area on the lower surface of each of the inner leads when the solder resist layer is formed on each of the inner leads.

10. The manufacturing method of the chip package structure as recited in claim 9, wherein each of the solder bumps covers the upper surface and at least part of the two side surfaces of the inner lead corresponding thereto when the solder bumps are reflowed.

11. The manufacturing method of the chip package structure as recited in claim 9, wherein the solder resist layer is a solder resist tape that is continuously adhered to the lower surfaces of the inner leads.

12. The manufacturing method of the chip package structure as recited in claim 9, wherein the solder resist layer further covers part of an area on the two side surfaces that the bonding area of each of the inner leads extends perpendicularly thereto.

13. The manufacturing method of the chip package structure as recited in claim 8, wherein the solder resist layer covers part of an area on the two side surfaces that the bonding area of each of the inner leads extends perpendicularly thereto when the solder resist layer is formed on each of the inner leads.

14. The manufacturing method of the chip package structure as recited in claim 13, wherein each of the solder bumps covers the upper surface and part of the two side surfaces of the inner lead corresponding thereto when the solder bumps are reflowed.

15. The manufacturing method of the chip package structure as recited in claim 8, further comprising:
removing the solder resist layer before forming the encapsulant.

16. The manufacturing method of the chip package structure as recited in claim 8, wherein the encapsulant further covers the solder resist layer when the encapsulant is formed.
